(19) United States
(12) Patent Application Publication
(10) Pub. No.: US 2025/0081859 A1
(43) Pub. Date: Mar. 6, 2025

(54) STRUCTURE, QUANTUM BIT, QUANTUM OPERATION DEVICE, AND METHOD FOR MANUFACTURING STRUCTURE

(71) Applicant: FUJITSU LIMITED, Kawasaki-shi (JP)

(72) Inventor: Junichi YAMAGUCHI, Atsugi (JP)

(73) Assignee: FUJITSU LIMITED, Kawasaki-shi (JP)

(21) Appl. No.: 18/948,638

(22) Filed: Nov. 15, 2024

Related U.S. Application Data
(63) Continuation of application No. PCT/JP2022/028919, filed on Jul. 27, 2022.

(51) Int. Cl. H10N 60/12; H10N 60/01; H10N 60/10; H10N 60/85

(52) U.S. Cl. CPC H10N 60/12; H10N 60/0912; H10N 60/128; H10N 60/85

(57) ABSTRACT

A method for manufacturing a structure includes: forming an s-wave superconductor layer over a base material; forming a first transition metal dichalcogenide layer that contains a van der Waals layered material, over the s-wave superconductor layer; and forming a second transition metal dichalcogenide layer over the first transition metal dichalcogenide layer.

### CROSS-REFERENCE TO RELATED APPLICATION

This application is a continuation application of International Application PCT/JP2022/028919 filed on Jul. 27, 2022 and designated the U.S., the entire contents of which are incorporated herein by reference.

### FIELD

The present disclosure discussed herein is related to a structure, a quantum bit, a quantum operation device, and a method for manufacturing the structure.

### BACKGROUND

A quantum operation device using Majorana particles has been studied. As a structure for generating the Majorana particles, a structure in which a two-dimensional topological insulator and an s-wave superconductor are combined has been proposed. As the two-dimensional topological insulator, a single-layer film of tungsten ditelluride (WTe₂) that is a layered material of transition metal dichalcogenide is used. Furthermore, a higher-order topological insulator layer including a multilayer film of WTe₂ has also been studied.

Japanese Laid-open Patent Publication No. 02-097485, Japanese National Publication of International Patent Application No. 2020-511780, U.S. Patent Application Publication No. 2014/0174343, U.S. Pat. No. 10,403,809, U.S. Patent Application Publication No. 2019/0131129, and Japanese Laid-open Patent Publication No. 2018-9201 are disclosed as related art.

N. Read and D. Green, Phys. Rev. B 61, 10267 (2000), V. Mourik et al., Science 336, 25 (2012), J. Alicea, Rep. Prog. Phys. 75, 076501 (2012), S. Wu et al., Science 359, 76 (2018), Y.-B. Choi et al., Nat. Mater 19, 974 (2020), and L. A. Walsh et al., 2D Mater. 4, 025044 (2017) are also disclosed as related art.

### SUMMARY

According to an aspect of the embodiments, a method for manufacturing a structure includes: forming an s-wave superconductor layer over a base material; forming a first transition metal dichalcogenide layer that contains a van der Waals layered material, over the s-wave superconductor layer; and forming a second transition metal dichalcogenide layer over the first transition metal dichalcogenide layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a structure according to a first embodiment;

FIG. 2 is a cross-sectional view (part 1) illustrating a method for manufacturing the structure according to the first embodiment;

FIG. 3 is a cross-sectional view (part 2) illustrating the method for manufacturing the structure according to the first embodiment;

FIG. 4 is a cross-sectional view (part 3) illustrating the method for manufacturing the structure according to the first embodiment;

FIG. 5 is a cross-sectional view (part 4) illustrating the method for manufacturing the structure according to the first embodiment;

FIG. 6 is a cross-sectional view (part 5) illustrating the method for manufacturing the structure according to the first embodiment;

FIG. 7 is a diagram (part 1) illustrating a result of scanning transmission electron microscope (STEM) observation;

FIG. 8 is a diagram (part 2) illustrating a result of the STEM observation;

FIG. 9 is a diagram illustrating a result of Raman spectrometry related to the first embodiment;

FIG. 10 is a top view illustrating a quantum bit according to a second embodiment;

FIG. 11 is a cross-sectional view (part 1) illustrating the quantum bit according to the second embodiment;

FIG. 12 is a cross-sectional view (part 2) illustrating the quantum bit according to the second embodiment;

FIG. 13 is a perspective view illustrating a higher-order topological insulator layer;

FIG. 14 is a top view (part 1) illustrating a method for manufacturing the quantum bit according to the second embodiment;

FIG. 15 is a top view (part 2) illustrating the method for manufacturing the quantum bit according to the second embodiment;

FIG. 16 is a top view (part 3) illustrating the method for manufacturing the quantum bit according to the second embodiment;

FIG. 17 is a top view (part 4) illustrating the method for manufacturing the quantum bit according to the second embodiment;

FIG. 18 is a top view (part 5) illustrating the method for manufacturing the quantum bit according to the second embodiment;

FIG. 19 is a top view (part 6) illustrating the method for manufacturing the quantum bit according to the second embodiment;

FIG. 20 is a cross-sectional view (part 1) illustrating the method for manufacturing the quantum bit according to the second embodiment;

FIG. 21 is a cross-sectional view (part 2) illustrating the method for manufacturing the quantum bit according to the second embodiment;

FIG. 22 is a cross-sectional view (part 3) illustrating the method for manufacturing the quantum bit according to the second embodiment;

FIG. 23 is a cross-sectional view (part 4) illustrating the method for manufacturing the quantum bit according to the second embodiment;

FIG. 24 is a cross-sectional view (part 5) illustrating the method for manufacturing the quantum bit according to the second embodiment;

FIG. 25 is a cross-sectional view (part 6) illustrating the method for manufacturing the quantum bit according to the second embodiment; and

FIG. 26 is a diagram illustrating a quantum operation device according to a third embodiment.

### DESCRIPTION OF EMBODIMENTS

Although proposals based on the theory have been made in the past, it is not easy to stably obtain a transition metal dichalcogenide layer of WTe2 or the like with excellent crystallinity.

An object of the present disclosure is to provide a structure, a quantum bit, a quantum operation device, a method for manufacturing the structure that can obtain excellent crystallinity in a transition metal dichalcogenide layer.

Hereinafter, embodiments of the present disclosure will be specifically described with reference to the accompanying drawings. Note that, in the present description and the drawings, components having substantially the same functional configuration will be denoted by the same reference sign, and redundant explanation will sometimes not be made. In the present disclosure, it is assumed that an X1-X2 direction, a Y1-Y2 direction, and a Z1-Z2 direction are directions orthogonal to each other. A plane including the X1-X2 direction and the Y1-Y2 direction is described as an XY plane, a plane including the Y1-Y2 direction and the Z1-Z2 direction is described as a YZ plane, and a plane including the Z1-Z2 direction and the X1-X2 direction is described as a ZX plane. Note that, for convenience, the Z1-Z2 direction is set as a vertical direction, and a Z1 side is set as an upper side, and a Z2 side is set as a lower side. Furthermore, a planar view refers to viewing an object from the Z1 side, and a planar shape refers to a shape of an object viewed from the Z1 side.

### First Embodiment

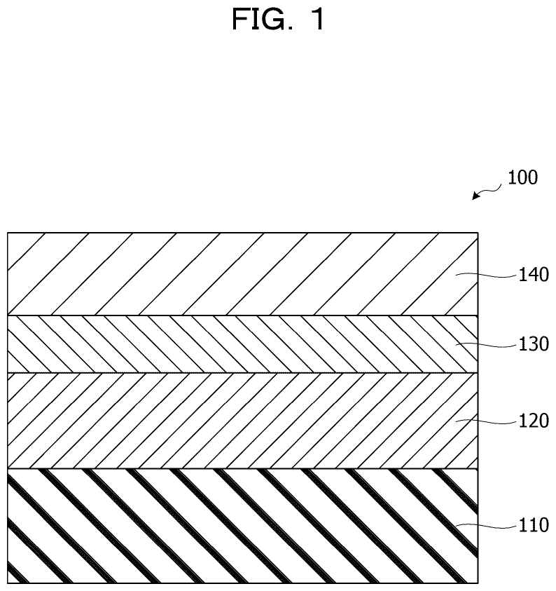

First, a first embodiment will be described. The first embodiment relates to a structure. FIG. 1 is a cross-sectional view illustrating the structure according to the first embodiment.

A structure 100 according to the first embodiment includes a substrate 110, an s-wave superconductor layer 120, a first transition metal dichalcogenide layer 130, and a second transition metal dichalcogenide layer 140. The s-wave superconductor layer 120 is formed over the substrate 110. The first transition metal dichalcogenide layer 130 is formed over the s-wave superconductor layer 120. The second transition metal dichalcogenide layer 140 is formed over the first transition metal dichalcogenide layer 130.

The substrate 110 is, for example, a single crystal substrate of which the Miller index of a surface is (100). A material of the substrate 110 is, for example, magnesium oxide (MgO). In the first embodiment, the substrate 110 is an example of a base material.

The s-wave superconductor layer 120 is, for example, a niobium (Nb) layer of which the Miller index of a surface is (100). A thickness of the s-wave superconductor layer 120 is, for example, about 40 nm.

The first transition metal dichalcogenide layer 130 contains a van der Waals layered material that is a two-dimensional material. The van der Waals layered material is, for example, niobium ditelluride (NbTe₂). The first transition metal dichalcogenide layer 130 includes a plurality of layers, for example, three layers, of NbTe₂. A thickness of the first transition metal dichalcogenide layer 130 is, for example, 1 nm to 5 nm.

The second transition metal dichalcogenide layer 140 includes, for example, a multilayer film of WTe₂. For example, the second transition metal dichalcogenide layer 140 includes a plurality of layers of WTe₂ that is a two-dimensional material. A thickness of the second transition metal dichalcogenide layer 140 is, for example, 1 nm to 5 nm.

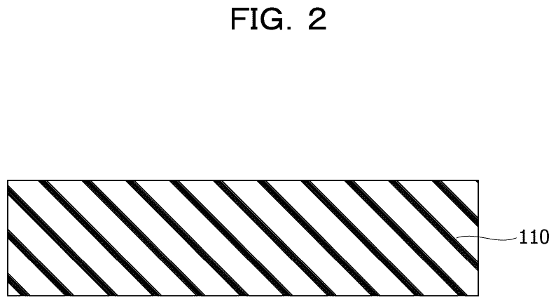

Next, a method for manufacturing the structure 100 according to the first embodiment will be described. FIGS. 2 to 6 are cross-sectional views illustrating a method for manufacturing the structure 100 according to the first embodiment. Here, it is assumed that a MgO single crystal substrate having a Miller index of (100) is used as the substrate 110, a Nb layer is formed as the s-wave superconductor layer 120, a NbTe₂ layer is formed as the first transition metal dichalcogenide layer 130, and a multilayer film of WTe₂ is formed as the second transition metal dichalcogenide layer 140.

First, as illustrated in FIG. 2, the substrate 110 (MgO single crystal substrate) is prepared, and annealing processing is performed on the substrate 110 for three hours to four hours at about 1200° C. under an oxygen atmosphere at atmospheric pressure. Next, the substrate 110 is immersed in methanol for 20 minutes to 30 minutes, and rinse processing is performed with ultrapure water. By these types of processing, flatness of a surface of the substrate 110 may be improved. For example, the surface of the substrate 110 will have atomic-level flatness.

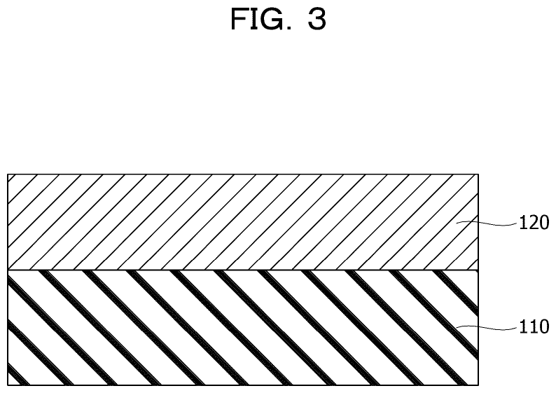

Thereafter, as illustrated in FIG. 3, the s-wave superconductor layer 120 (Nb layer) is formed over the substrate 110. The s-wave superconductor layer 120 can be epitaxially grown by, for example, a pulse laser deposition (PLD) method. For example, a thickness of the s-wave superconductor layer 120 is set to about 40 nm.

When the s-wave superconductor layer 120 is formed by the PLD method, for example, a basic degree of vacuum is set to 5×10⁻⁶ Pa or less, and a krypton fluoride (KrF) excimer laser (λ=248 nm) light source can be used as a laser light source. When the s-wave superconductor layer 120 is formed, for example, a Nb pure metal target can be used as a target. When the s-wave superconductor layer 120 is formed, for example, a temperature of the substrate 110 is held at about 950° C., a laser energy density is set to 2.0 J/cm2, an irradiation frequency is set to 10 Hz, a distance between the substrate 110 and the target is set to about 5 cm, and a film formation rate is set to 1.0 nm/minute. Over the substrate 110 held at about 950° C., the Nb layer is epitaxially grown while being oriented in a direction. After the epitaxial growth, post-annealing is preferably performed at 1100° C. to 1200° C. for 10 minutes. The post-annealing may improve the flatness of a surface of the s-wave superconductor layer 120. For example, the surface of the s-wave superconductor layer 120 will have atomic-level flatness.

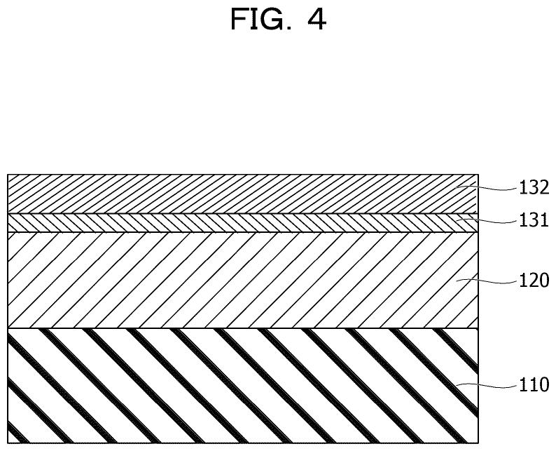

Next, as illustrated in FIG. 4, a chalcogen layer 131 is formed over the s-wave superconductor layer 120, and a metal layer 132 containing a transition metal is formed over the chalcogen layer 131. Here, it is assumed that a tellurium (Te) layer is formed as the chalcogen layer 131, and a Nb layer is formed as the metal layer 132. For example, a thickness of the chalcogen layer 131 is set to 20 nm, and a thickness of the metal layer 132 is set to 2 nm.

When the chalcogen layer 131 is formed by the PLD method, for example, a basic degree of vacuum is set to 5×10⁻⁶ Pa or less, and a KrF excimer laser (λ=248 nm) light source can be used as a laser light source. When the chalcogen layer 131 is formed, for example, a Te pure metal target can be used as a target. When the chalcogen layer 131 is formed, for example, a temperature of the substrate 110 is held at room temperature, a laser energy density is set to 1.0 J/cm², an irradiation frequency is set to 1 Hz, a distance between the substrate 110 and the target is set to about 5 cm, and a film formation rate is set to 10.0 nm/minute.

When the metal layer 132 is formed by the PLD method, for example, a basic degree of vacuum is set to 5×10⁻⁶ Pa or less, and a KrF excimer laser (λ=248 nm) light source can be used as a laser light source. When the metal layer 132 is formed, for example, a Nb pure metal target can be used as a target. When the metal layer 132 is formed, for example, a temperature of the substrate 110 is held at room temperature, a laser energy density is set to 2.0 J/cm², an irradiation frequency is set to 10 Hz, a distance between the substrate 110 and the target is set to about 5 cm, and a film formation rate is set to 1.0 nm/minute.

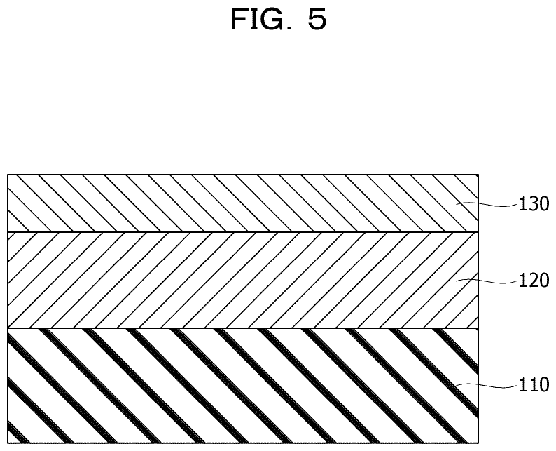

After the formation of the metal layer 132, post-annealing is performed at 250° C. to 350° C. for one hour. For example, the chalcogen layer 131 and the metal layer 132 are heated. As a result, as illustrated in FIG. 5, NbTe₂ that is a van der Waals layered material is produced from Te contained in the chalcogen layer 131 and Nb contained in the metal layer 132, and the first transition metal dichalcogenide layer 130 (NbTe₂ layer) containing NbTe₂ is formed. Nb contained in the s-wave superconductor layer 120 may also be used to form the first transition metal dichalcogenide layer 130. Furthermore, a part of the chalcogen layer 131 may remain after the formation of the first transition metal dichalcogenide layer 130. Although a vapor pressure of Te is relatively low, since the metal layer 132 is formed over the chalcogen layer 131, the metal layer 132 functions as a cap layer, and rapid evaporation of Te in the chalcogen layer 131 attributable to heating is suppressed. The first transition metal dichalcogenide layer 130 is formed in layers over the s-wave superconductor layer 120, and a crystal structure of the first transition metal dichalcogenide layer 130 exhibits a 1T structure. A thickness of the first transition metal dichalcogenide layer 130 is, for example, 1 nm to 5 nm.

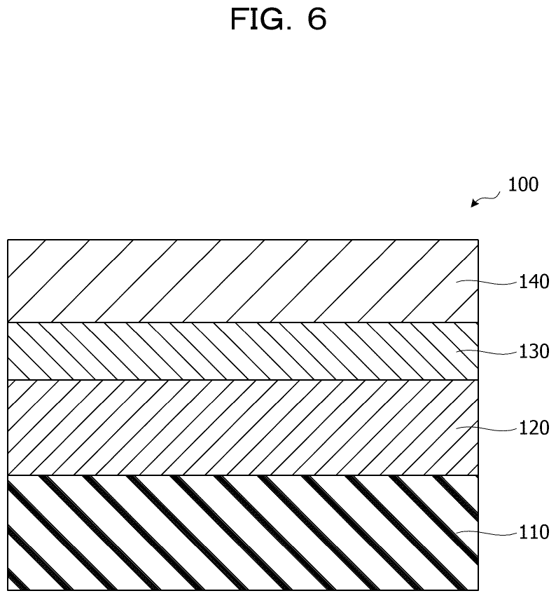

Next, as illustrated in FIG. 6, the second transition metal dichalcogenide layer 140 (a multilayer film of WTe₂) is formed over the first transition metal dichalcogenide layer 130. The second transition metal dichalcogenide layer 140 can be epitaxially grown by, for example, the PLD method. For example, a thickness of the second transition metal dichalcogenide layer 140 is set to about 1 nm to 5 nm.

When the second transition metal dichalcogenide layer 140 is formed by the PLD method, for example, a basic degree of vacuum is set to 5×10⁻⁶ Pa or less, and a KrF excimer laser (λ=248 nm) light source can be used as a laser light source. When the second transition metal dichalcogenide layer 140 is formed, for example, a WTe₂ sintered body target can be used as a target. When the second transition metal dichalcogenide layer 140 is formed, for example, a temperature of the substrate 110 is held at about 325° C., a laser energy density is set to 1.0 J/cm², an irradiation frequency is set to 10 Hz, a distance between the substrate 110 and the target is set to about 5 cm, and a film formation rate is set to 1.0 nm/minute. The second transition metal dichalcogenide layer 140 is epitaxially grown over the first transition metal dichalcogenide layer 130. A crystal structure of the second transition metal dichalcogenide layer 140 exhibits a Td structure.

The s-wave superconductor layer 120 and the second transition metal dichalcogenide layer 140 can be epitaxially grown in situ, for example, in a same vacuum chamber. The s-wave superconductor layer 120, the chalcogen layer 131, the metal layer 132, and the second transition metal dichalcogenide layer 140 can be formed by a physical vapor deposition method in a vacuum integrated process. The method for forming the s-wave superconductor layer 120, the chalcogen layer 131, the metal layer 132, and the second transition metal dichalcogenide layer 140 is not limited to the PLD method. For example, the formation may be done by a molecular beam epitaxy (MBE) method, a sputtering method, or a vapor deposition method.

In this way, the structure 100 according to the first embodiment can be manufactured.

In the structure 100, the first transition metal dichalcogenide layer 130 functions as a seed layer when the second transition metal dichalcogenide layer 140 is formed. Accordingly, excellent crystallinity may be obtained in the second transition metal dichalcogenide layer 140. For example, in the present embodiment, the first transition metal dichalcogenide layer 130 contains a van der Waals layered material, and a top surface of the first transition metal dichalcogenide layer 130 is an inactive surface in which dangling bonds are suppressed. Accordingly, the second transition metal dichalcogenide layer 140 having excellent crystallinity can be heteroepitaxially grown.

After the film formation for the second transition metal dichalcogenide layer 140, post-annealing is preferably performed at about 300° C. for 30 minutes to one hour. This is because the crystallinity of the second transition metal dichalcogenide layer 140 is improved.

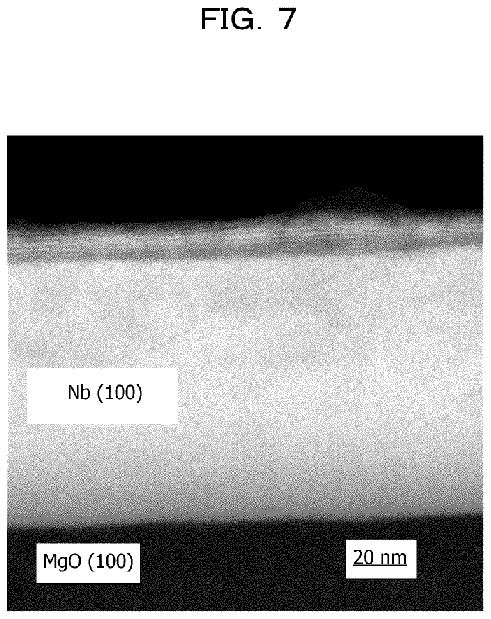

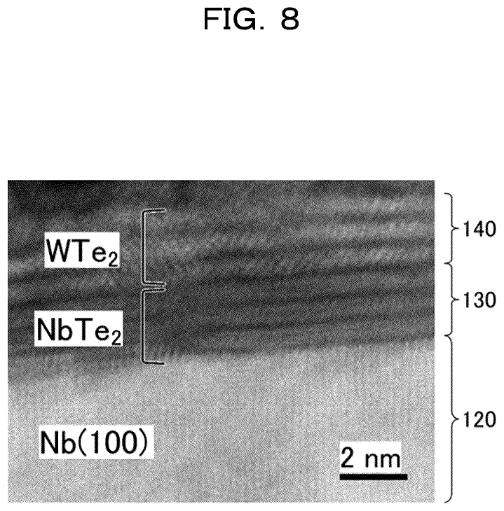

Next, results of scanning transmission electron microscope (STEM) observation related to the first embodiment performed by the present inventors will be described. In this observation, a sample was created in accordance with the first embodiment, and this sample was subjected to the STEM observation. Note that a laminated film of three layers of NbTe₂ was formed as the first transition metal dichalcogenide layer 130, and a laminated film of three layers of WTe₂ was formed as the second transition metal dichalcogenide layer 140. FIGS. 7 and 8 are diagrams illustrating results of the STEM observation. FIG. 7 illustrates a wide-field image by a high-angle annular dark field (HAADF) method, and FIG. 8 illustrates a narrow-field image by a high-resolution HAADF method. In FIGS. 7 and 8, “Nb (100)” indicates that the s-wave superconductor layer 120 is a Nb layer of which the Miller index of a surface (top surface) is (100).

As illustrated in FIG. 7, the second transition metal dichalcogenide layer 140 uniformly grown over at least several tens of nm in a plane parallel to the surface of the s-wave superconductor layer 120 was observed. Furthermore, as illustrated in FIG. 8, the first transition metal dichalcogenide layer 130 (NbTe₂ layer) and the second transition metal dichalcogenide layer 140 (WTe₂ layer) epitaxially grown by three layers each were observed over the s-wave superconductor layer 120. The contrasts are different between the first transition metal dichalcogenide layer 130 and the second transition metal dichalcogenide layer 140. Note that a thickness of NbTe₂ of one layer and a thickness of WTe₂ of one layer are both about 0.7 nm.

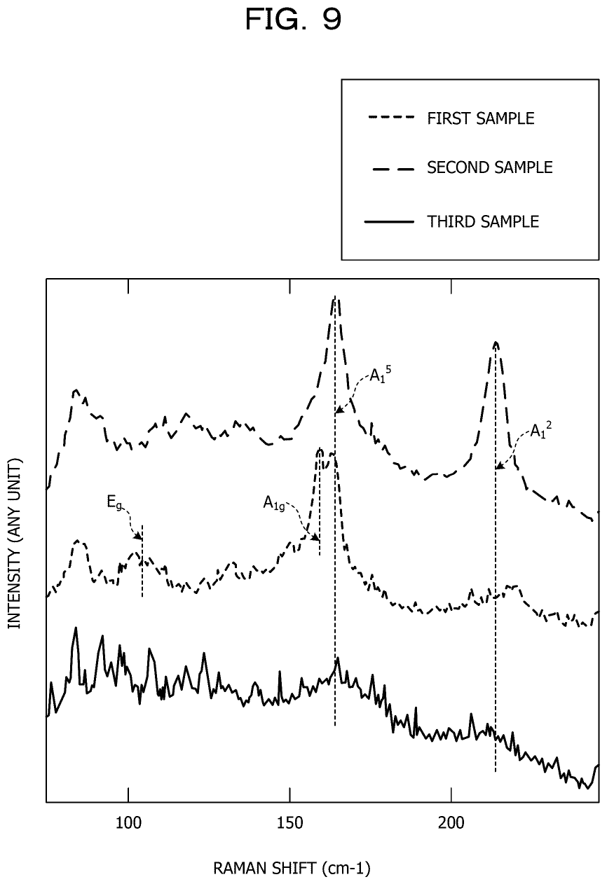

Next, a result of Raman spectrometry related to the first embodiment performed by the present inventors will be described. In this measurement, a sample (first sample) similar to the sample used for the STEM observation was created, and Raman spectrometry was performed on the first sample. Furthermore, a second sample and a third sample were also created, and Raman spectrometry was also performed on the second sample and the third sample. The second sample is a sample in which the number of layers of the WTe₂ layers included in the second transition metal dichalcogenide layer 140 is set to 12. The third sample is a sample in which the second transition metal dichalcogenide layer 140 (12 layers of WTe₂) is formed over the s-wave superconductor layer 120 without forming the first transition metal dichalcogenide layer 130. Other configurations of the second sample and the third sample are similar to that of the first sample. FIG. 9 is a diagram illustrating a result of Raman spectrometry related to the first embodiment.

As illustrated in FIG. 9, in the first sample, in addition to phonon modes of A₁² (213 cm⁻¹) and A₁⁵ (164 cm⁻¹) derived from WTe₂, phonon modes of A_{1g} (159 cm⁻¹) and E_{g} (103 cm⁻¹) derived from NbTe₂ were also found. In the second sample, peak intensities of A₁² and A₁⁵ increased due to an increase in the number of layers of WTe₂, as compared with the first sample. On the other hand, in the third sample, although the number of layers of WTe₂ was large, peak intensities of A₁² and A₁⁵ were low. This result indicates that the crystallinity of the second transition metal dichalcogenide layer 140 is lower in the third sample than in the second sample. From the above results, it may be said that the first transition metal dichalcogenide layer 130 contributes to improvement of the crystallinity of the second transition metal dichalcogenide layer 140.

### Second Embodiment

Next, a second embodiment will be described. The second

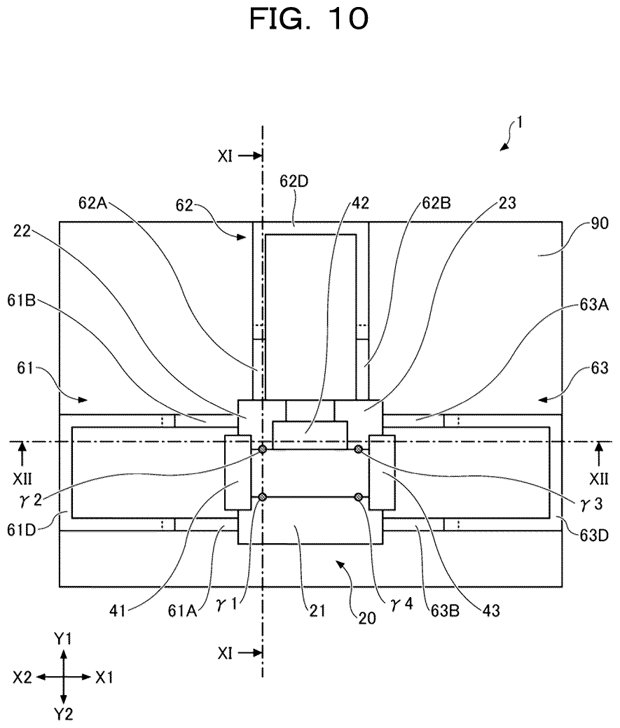

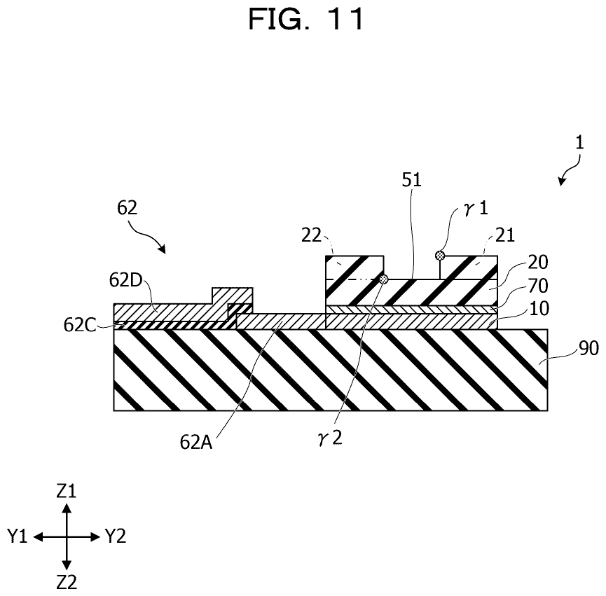

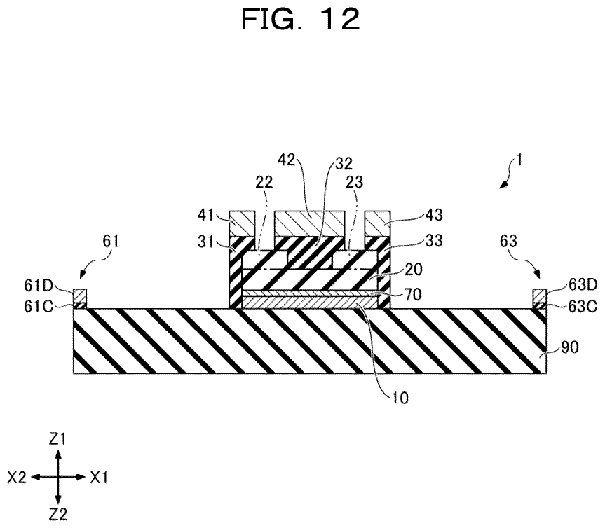

embodiment relates to a quantum bit. The quantum bit according to the second embodiment is used for a quantum operation device such as a quantum computer, for example. FIG. 10 is a top view illustrating the quantum bit according to the second embodiment. FIGS. 11 and 12 are cross-sectional views illustrating the quantum bit according to the second embodiment. FIG. 11 corresponds to a cross-sectional view taken along line XI-XI in FIG. 10. FIG. 12 corresponds to a cross-sectional view taken along line XII-XII in FIG. 10.

A quantum bit 1 according to the second embodiment includes a substrate 90, an s-wave superconductor layer 10, a transition metal dichalcogenide layer 70, a higher-order topological insulator layer 20, a first ferromagnetic insulator layer 31, a second ferromagnetic insulator layer 32, and a third ferromagnetic insulator layer 33. The quantum bit 1 further includes a first gate electrode 41, a second gate electrode 42, a third gate electrode 43, a first superconducting quantum interference device (SQUID) 61, a second SQUID 62, and a third SQUID 63.

The substrate 90 is, for example, a single crystal substrate of which the Miller index of a surface is (100). As a material of the substrate 90, MgO, mica, sapphire, and silicon carbide (SiC) are exemplified. The substrate 90 may be a silicon (Si) substrate with a thermally oxidized film.

The s-wave superconductor layer 10 is provided on a part of the surface of the substrate 90. The s-wave superconductor layer 10 is, for example, a Nb layer of which the Miller index of the surface is (100). A thickness of the s-wave superconductor layer 10 is, for example, about 40 nm. A planar shape of the s-wave superconductor layer 10 is a rectangle having two sides parallel to the X1-X2 direction and two sides parallel to the Y1-Y2 direction.

The transition metal dichalcogenide layer 70 is provided over the s-wave superconductor layer 10. The transition metal dichalcogenide layer 70 includes a van der Waals layered material that is a two-dimensional material. The van der Waals layered material is, for example, NbTe₂. The transition metal dichalcogenide layer 70 includes a plurality of layers of NbTe₂. A thickness of the transition metal dichalcogenide layer 70 is, for example, 2 nm. The transition metal dichalcogenide layer 70 is also an example of the first transition metal dichalcogenide layer.

The higher-order topological insulator layer 20 is provided over the transition metal dichalcogenide layer 70. The higher-order topological insulator layer 20 includes, for example, a multilayer film of WTe₂. For example, the higher-order topological insulator layer 20 includes a plurality of layers of WTe₂ that is a two-dimensional material. A thickness of the higher-order topological insulator layer 20 is, for example, 10 nm. The higher-order topological insulator layer 20 is also an example of the second transition metal dichalcogenide layer.

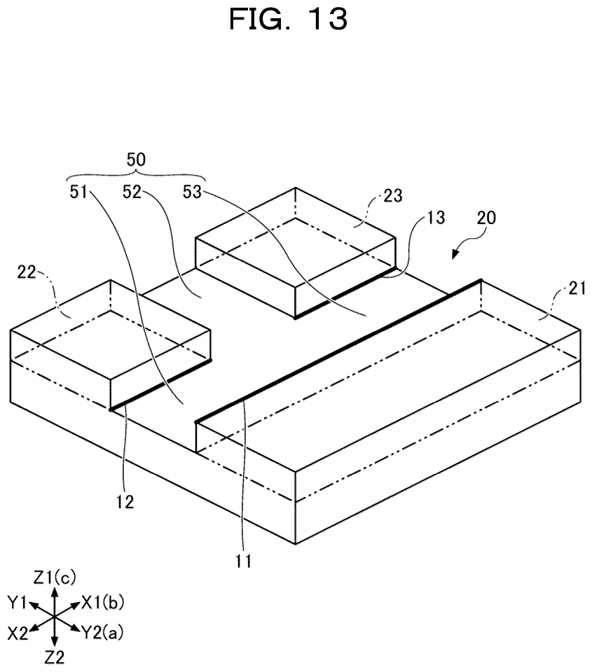

FIG. 13 is a perspective view illustrating the higher-order topological insulator layer 20. A shape of the higher-order topological insulator layer 20 is substantially a rectangular parallelepiped. An a-axis direction of the higher-order topological insulator layer 20 is parallel to the Y1-Y2 direction, a b-axis direction is parallel to the X1-X2 direction, and a c-axis direction is parallel to the Z1-Z2 direction. A Miller index of a top surface of the higher-order topological insulator layer 20 is (001), a Miller index of a side surface on a Y2 side is (100), and a Miller index of a side surface on an X1 side is (010).

In a surface of the higher-order topological insulator layer 20, a groove 50 having a T-shape in planar view is formed. The groove 50 includes a first groove 51, a second groove 52, and a third groove 53. For example, a width of each of the first groove 51, the second groove 52, and the third groove 53 is 20 nm, and a depth of each of the first groove 51, the second groove 52, and the third groove 53 is 5 nm. The first groove 51 and the third groove 53 extend in parallel to the X1-X2 direction, and the second groove 52 extends in parallel to the Y1-Y2 direction. The first groove 51 is provided in the vicinity of a center of the higher-order topological insulator layer 20 in the Y1-Y2 direction and extends from an end on an X2 side to a center in the X1-X2 direction of the higher-order topological insulator layer 20. The third groove 53 is provided in the vicinity of the center of the higher-order topological insulator layer 20 in the Y1-Y2 direction and extends from an end on the X1 side to the center in the X1-X2 direction of the higher-order topological insulator layer 20. Therefore, the first groove 51 and the third groove 53 are formed in a straight line. The second groove 52 is provided in the vicinity of the center of the higher-order topological insulator layer 20 in the X1-X2 direction and extends from an end on a Y1 side to a center in the Y1-Y2 direction of the higher-order topological insulator layer 20. Therefore, the second groove 52 is orthogonal to the first groove 51 and the third groove 53.

The higher-order topological insulator layer 20 includes a first region 21 on a Y2 side of the first groove 51 and the third groove 53. The higher-order topological insulator layer 20 includes a second region 22 on the Y1 side of the first groove 51 and on the X2 side of the second groove 52. The higher-order topological insulator layer 20 includes a third region 23 on the Y1 side of the third groove 53 and on the X1 side of the second groove 52.

Each of the first region 21, the second region 22, and the third region 23 includes a hinge helical channel on one of two intersecting lines of a plane perpendicular to the a-axis direction and a plane perpendicular to the c-axis direction. The hinge helical channel is parallel to the b-axis direction. For example, the first region 21 includes a first hinge helical channel 11 on an intersecting line (ridge line) between a top surface and a side surface on the Y1 side. The second region 22 includes a second hinge helical channel 12 on an intersecting line between a side surface on the Y2 side and a bottom surface of the first groove 51. The third region 23 includes a third hinge helical channel 13 on an intersecting line between a side surface on the Y2 side and a bottom surface of the third groove 53. The first hinge helical channel 11 may be provided on an intersecting line between the side surface of the first region 21 on the Y1 side and a bottom surface of the groove 50, the second hinge helical channel 12 may be provided on an intersecting line between the top surface and the side surface on the Y2 side of the second region 22, and the third hinge helical channel 13 may be provided on an intersecting line between the top surface and the side surface on the Y2 side of the third region 23.

The first ferromagnetic insulator layer 31 is provided over a part of the first region 21, the second region 22, and the groove 50 and covers a part of the first hinge helical channel 11 and the second hinge helical channel 12. The second ferromagnetic insulator layer 32 is provided over a part of the second region 22, the third region 23, and the groove 50 and covers a part of the second hinge helical channel 12 and the third hinge helical channel 13. The third ferromagnetic insulator layer 33 is provided over a part of the third region 23, the first region 21, and the groove 50 and covers a part of the third hinge helical channel 13 and the first hinge helical channel 11. As a material of the first ferromagnetic insulator layer 31, the second ferromagnetic insulator layer 32, and the third ferromagnetic insulator layer 33, dichromium digallium hexatelluride (Cr₂Ga₂Te₆) is exemplified. The materials of the first ferromagnetic insulator layer 31, the second ferromagnetic insulator layer 32, and the third ferromagnetic insulator layer 33 may be other diluted magnetic semiconductors. Thicknesses of the first ferromagnetic insulator layer 31, the second ferromagnetic insulator layer 32, the third ferromagnetic insulator layer 33 are, for example, each about 30 nm.

The second ferromagnetic insulator layer 32 is separated from the first ferromagnetic insulator layer 31 in the X1-X2 direction toward the X1 side over the second hinge helical channel 12. The third ferromagnetic insulator layer 33 is separated from the second ferromagnetic insulator layer 32 in the X1-X2 direction toward the X1 side over the third hinge helical channel 13. The third ferromagnetic insulator layer 33 is separated from the first ferromagnetic insulator layer 31 in the X1-X2 direction toward the X1 side over the first hinge helical channel 11.

The first gate electrode 41 is provided over the first ferromagnetic insulator layer 31. The second gate electrode 42 is provided over the second ferromagnetic insulator layer 32. The third gate electrode 43 is provided over the third ferromagnetic insulator layer 33. As a material of the first gate electrode 41, the second gate electrode 42, and the third gate electrode 43, gold (Au) is exemplified. Thicknesses of the first gate electrode 41, the second gate electrode 42, and the third gate electrode 43 are, for example, each about 50 nm.

The first SQUID 61 includes a lower superconductor layer 61A, a lower superconductor layer 61B, a tunnel barrier layer 61C, and an upper superconductor layer 61D.

The lower superconductor layers 61A and 61B protrude toward the X2 side from a side surface of the s-wave superconductor layer 10 on the X2 side. The lower superconductor layer 61A is provided on the Y2 side of the lower superconductor layer 61B. In planar view, the lower superconductor layer 61A protrudes toward the X2 side from the first region 21, and the lower superconductor layer 61B protrudes toward the X2 side from the second region 22. The lower superconductor layers 61A and 61B are formed integrally with the s-wave superconductor layer 10 from a material same as that of the s-wave superconductor layer 10. The lower superconductor layers 61A and 61B are connected to the s-wave superconductor layer 10. The lower superconductor layers 61A and 61B are, for example, Nb layers having a thickness of about 40 nm.

The tunnel barrier layer 61C and the upper superconductor layer 61D have a U-shaped planar shape. As a material of the tunnel barrier layer 61C, niobium oxide (NbOₓ) is exemplified, and as a material of the upper superconductor layer 61D, Nb is exemplified. A thickness of the tunnel barrier layer 61C is, for example, about 1 nm to 5 nm, and a thickness of the upper superconductor layer 61D is, for example, about 40 nm. One end portion of the tunnel barrier layer 61C has contact with the lower superconductor layer 61A, and another end portion has contact with the lower superconductor layer 61B. The upper superconductor layer 61D is provided over the tunnel barrier layer 61C.

The tunnel barrier layer 61C is sandwiched between the lower superconductor layer 61A and the upper superconductor layer 61D and between the lower superconductor layer 61B and the upper superconductor layer 61D. The first SQUID 61 is configured by such Josephson junction. The first SQUID 61 detects a change in a magnetic flux between the first hinge helical channel 11 and the second hinge helical channel 12.

The second SQUID 62 includes a lower superconductor layer 62A, a lower superconductor layer 62B, a tunnel barrier layer 62C, and an upper superconductor layer 62D.

The lower superconductor layers 62A and 62B protrude toward the Y1 side from a side surface of the s-wave superconductor layer 10 on the Y1 side. The lower superconductor layer 62A is provided on the X2 side of the lower superconductor layer 62B. In planar view, the lower superconductor layer 62A protrudes toward the Y1 side from the second region 22, and the lower superconductor layer 62B protrudes toward the Y1 side from the third region 23. The lower superconductor layers 62A and 62B are formed integrally with the s-wave superconductor layer 10 from a material same as that of the s-wave superconductor layer 10. The lower superconductor layers 62A and 62B are connected to the s-wave superconductor layer 10. The lower superconductor layers 62A and 62B are, for example, Nb layers having a thickness of about 40 nm.

The tunnel barrier layer 62C and the upper superconductor layer 62D have a U-shaped planar shape. As a material of the tunnel barrier layer 62C, NbOₓ is exemplified, and as a material of the upper superconductor layer 62D, Nb is exemplified. A thickness of the tunnel barrier layer 62C is, for example, about 1 nm to 5 nm, and a thickness of the upper superconductor layer 62D is, for example, about 40 nm. One end portion of the tunnel barrier layer 62C has contact with the lower superconductor layer 62A, and another end portion has contact with the lower superconductor layer 62B. The upper superconductor layer 62D is provided over the tunnel barrier layer 62C.

The tunnel barrier layer 62C is sandwiched between the lower superconductor layer 62A and the upper superconductor layer 62D and between the lower superconductor layer 62B and the upper superconductor layer 62D. The second SQUID 62 is configured by such Josephson junction. The second SQUID 62 detects a change in a magnetic flux between the second hinge helical channel 12 and the third hinge helical channel 13.

The third SQUID 63 includes a lower superconductor layer 63A, a lower superconductor layer 63B, a tunnel barrier layer 63C, and an upper superconductor layer 63D.

The lower superconductor layers 63A and 63B protrude toward the X1 side from a side surface of the s-wave superconductor layer 10 on the X1 side. The lower superconductor layer 63A is provided on the Y1 side of the lower superconductor layer 63B. In planar view, the lower superconductor layer 63A protrudes toward the X1 side from the third region 23, and the lower superconductor layer 63B protrudes toward the X1 side from the first region 21. The lower superconductor layers 63A and 63B are formed integrally with the s-wave superconductor layer 10 from a material same as that of the s-wave superconductor layer 10. The lower superconductor layers 63A and 63B are connected to the s-wave superconductor layer 10. The lower superconductor layers 63A and 63B are, for example, Nb layers having a thickness of about 40 nm.

The tunnel barrier layer 63C and the upper superconductor layer 63D have a U-shaped planar shape. As a material of the tunnel barrier layer 63C, NbOₓ is exemplified, and as a material of the upper superconductor layer 63D, Nb is exemplified. A thickness of the tunnel barrier layer 63C is, for example, about 1 nm to 5 nm, and a thickness of the upper superconductor layer 63D is, for example, about 40 nm. One end portion of the tunnel barrier layer 63C has contact with the lower superconductor layer 63A, and another end portion has contact with the lower superconductor layer 63B. The upper superconductor layer 63D is provided over the tunnel barrier layer 63C.

The tunnel barrier layer 63C is sandwiched between the lower superconductor layer 63A and the upper superconductor layer 63D and between the lower superconductor layer 63B and the upper superconductor layer 63D. The third SQUID 63 is configured by such Josephson junction. The third SQUID 63 detects a change in a magnetic flux between the third hinge helical channel 13 and the first hinge helical channel 11.

In the quantum bit 1 configured in this way, four types of Majorana particles γ1, γ2, γ3, and γ4 are expressed. For example, the Majorana particle γ1 is stably expressed in the vicinity of the first gate electrode 41 of the first hinge helical channel 11, and the Majorana particle γ4 is stably expressed in the vicinity of the third gate electrode 43 of the first hinge helical channel 11. Furthermore, for example, the Majorana particle γ2 is stably expressed between the first gate electrode 41 and the second gate electrode 42 of the second hinge helical channel 12, and the Majorana particle γ3 is stably expressed between the second gate electrode 42 and the third gate electrode 43 of the third hinge helical channel 13. Then, exchange of the Majorana particles γ1 to γ4 is performed by a change in an electrostatic potential caused by application of a gate voltage to the first gate electrode 41, the second gate electrode 42, and the third gate electrode 43.

For example, in the exchange of the Majorana particles γ1 and γ2, an electric field is applied from the first gate electrode 41, and a minute change in the magnetic flux at the time of the exchange of the Majorana particles γ1 and γ2 is detected by the first SQUID 61 as a minute change in a voltage signal. In the exchange of the Majorana particles γ2 and γ3, an electric field is applied from the second gate electrode 42, and a minute change in the magnetic flux at the time of the exchange of the Majorana particles γ2 and γ3 is detected by the second SQUID 62 as a minute change in a voltage signal. Furthermore, in the exchange of the Majorana particles γ3 and γ4, an electric field is applied from the third gate electrode 43, and a minute change in the magnetic flux at the time of the exchange of the Majorana particles γ3 and γ4 is detected by the third SQUID 63 as a minute change in a voltage signal.

A single-layer film of WTe₂ that is a layered material of transition metal dichalcogenide is easily oxidized, and properties change when exposed to the atmosphere. By sandwiching the single-layer film of WTe₂ with chemically stable substances such as hexagonal boron nitride (h-BN) or graphene, it is possible to suppress oxidation. However, in that case, a process for manufacturing the quantum bit is complicated. Furthermore, it is also difficult to adjust a size of the single-layer film of WTe₂. In contrast to this, in the present embodiment, since the higher-order topological insulator layer 20 including a multilayer film of WTe₂ or the like is used, a configuration for suppressing the oxidation is not needed. Furthermore, the adjustment of the size of the higher-order topological insulator layer 20 is easier than the adjustment of the size of the single-layer film of WTe₂.

Furthermore, it is also possible to provide a plurality of the quantum bits 1 over the substrate 90 to perform multi-quantization or to implement a semiconductor integrated circuit over the substrate 90. Therefore, according to the present embodiment, it is possible to accelerate research and development for realizing a practical error resistant quantum computer.

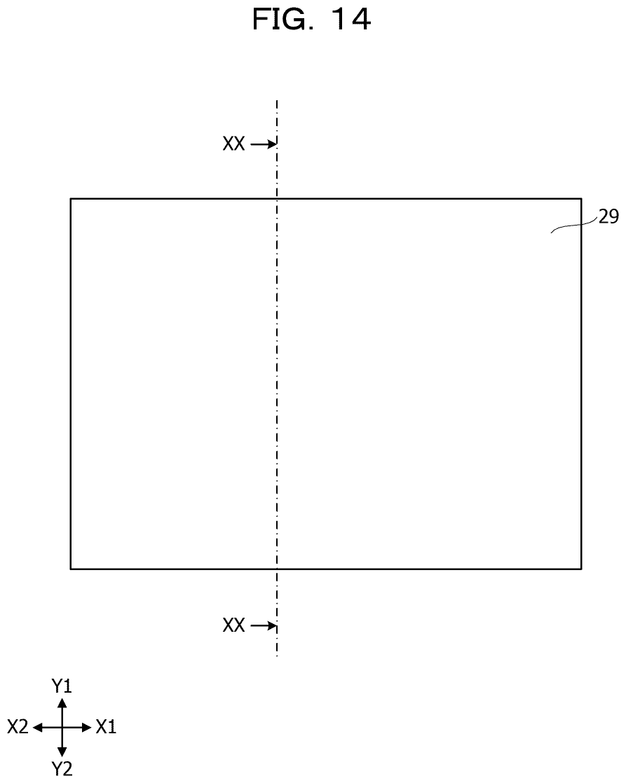

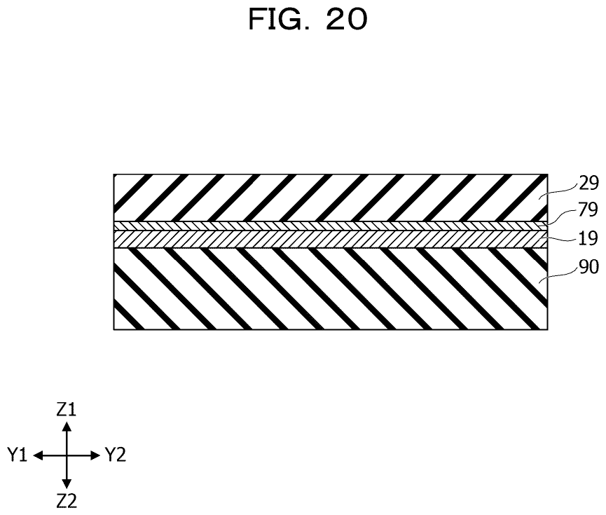

Next, a method for manufacturing the quantum bit 1 according to the second embodiment will be described. FIGS. 14 to 19 are top views illustrating the method for manufacturing the quantum bit 1 according to the second embodiment. FIGS. 20 to 25 are cross-sectional views illustrating the method for manufacturing the quantum bit 1 according to the second embodiment.

First, as illustrated in FIGS. 14 to 20, the substrate 90 is prepared, and annealing processing is performed on the substrate 90 for three hours to four hours at about 1200° C. under an oxygen atmosphere at atmospheric pressure. Next, the substrate 90 is immersed in methanol for 20 minutes to 30 minutes, and rinse processing is performed with ultrapure water. By these types of processing, flatness of the surface of the substrate 90 may be improved. FIG. 20 corresponds to a cross-sectional view taken along line XX-XX in FIG. 14.

Thereafter, an s-wave superconductor layer 19 is formed over the substrate 90, a first transition metal dichalcogenide layer 79 is formed over the s-wave superconductor layer 19, and a higher-order topological insulator layer 29 is formed over the first transition metal dichalcogenide layer 79. For example, a Nb layer is formed as the s-wave superconductor layer 19, a NbTe₂ layer is formed as the first transition metal dichalcogenide layer 79, and a multilayer film of WTe₂ is formed as the higher-order topological insulator layer 29. The s-wave superconductor layer 19, the first transition metal dichalcogenide layer 79, and the higher-order topological insulator layer 29 can be formed by methods similar to the methods for the s-wave superconductor layer 120, the first transition metal dichalcogenide layer 130, and the second transition metal dichalcogenide layer 140 in the first embodiment, respectively.

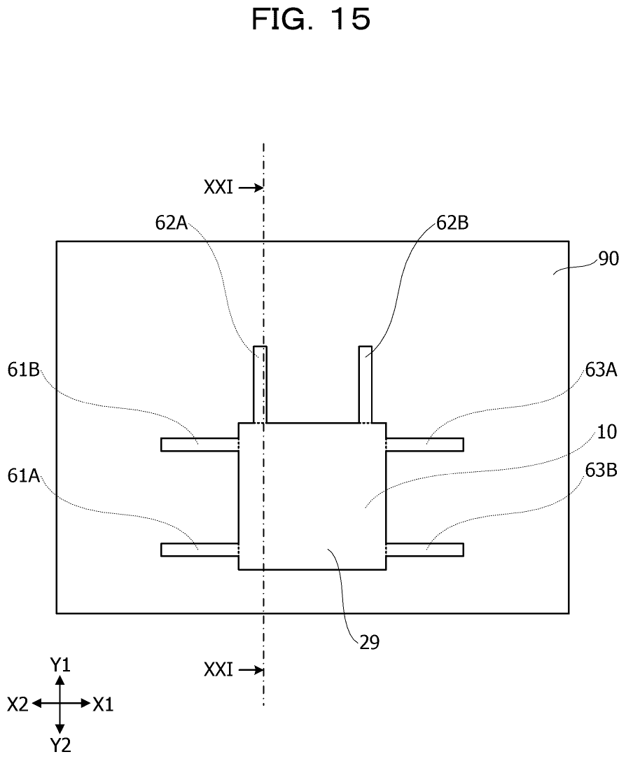

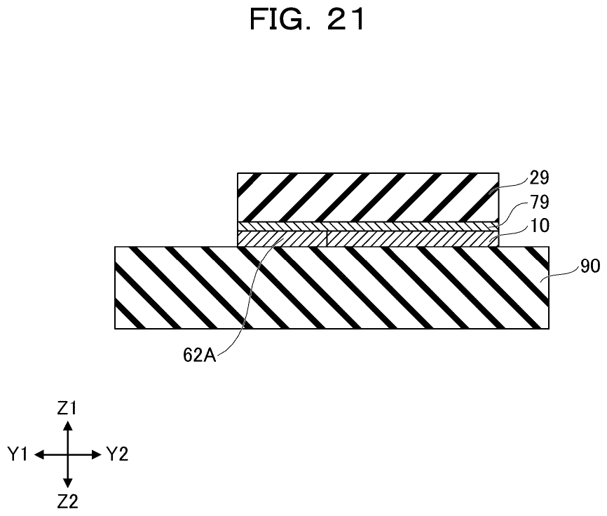

After the formation of the higher-order topological insulator layer 29, as illustrated in FIGS. 15 and 21, the s-wave superconductor layer 19, the first transition metal dichalcogenide layer 79, and the higher-order topological insulator layer 29 are processed, and the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B are formed from the s-wave superconductor layer 19. FIG. 21 corresponds to a cross-sectional view taken along line XXI-XXI in FIG. 15.

When the s-wave superconductor layer 19, the first transition metal dichalcogenide layer 79, and the higher-order topological insulator layer 29 are processed, first, the higher-order topological insulator layer 29 is spin-coated from above with a first electron beam resist. Next, a first mask pattern is formed from the first electron beam resist by electron beam lithography. The first mask pattern covers portions of the s-wave superconductor layer 19 where the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B are intended to be formed, from above the higher-order topological insulator layer 29, and exposes other portions. As the first electron beam resist, for example, a resist obtained by diluting ZEP 520A (manufactured by Zeon Corporation) with ZEP-A (manufactured by Zeon Corporation) at 1:1 can be used. After the formation of the first mask pattern, the s-wave superconductor layer 19, the first transition metal dichalcogenide layer 79, and the higher-order topological insulator layer 29 are processed by argon (Ar) ion milling. In the Ar ion milling, for example, a beam acceleration voltage is set to 280 V, and a beam current is set to 150 mA.

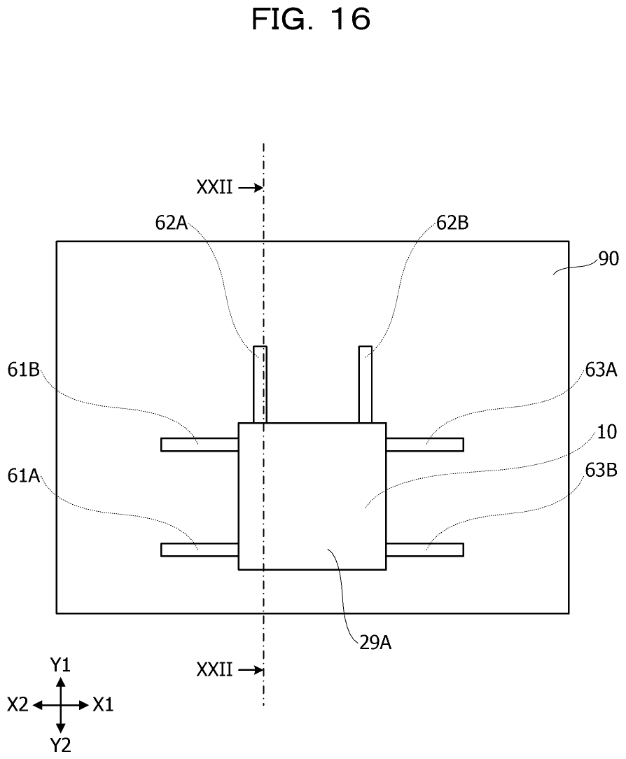

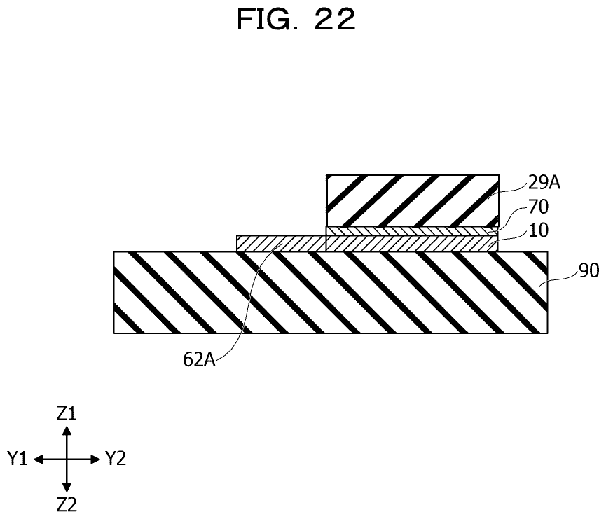

After the processing of the s-wave superconductor layer 19, the first transition metal dichalcogenide layer 79, and the higher-order topological insulator layer 29, the first mask pattern is removed, and as illustrated in FIGS. 16 and 22, the higher-order topological insulator layer 29 and the first transition metal dichalcogenide layer 79 are processed to form a higher-order topological insulator layer 29A having a rectangular planar shape and a flat top surface from the higher-order topological insulator layer 29 and form the transition metal dichalcogenide layer 70 having a rectangular planar shape from the first transition metal dichalcogenide layer 79. FIG. 22 corresponds to a cross-sectional view taken along line XXII-XXII in FIG. 16.

When the higher-order topological insulator layer 29 and the first transition metal dichalcogenide layer 79 are processed, first, the higher-order topological insulator layer 29 and the substrate 90 are spin-coated from above with a second electron beam resist. Next, a second mask pattern is formed from the second electron beam resist by the electron beam lithography. The second mask pattern covers a portion of the higher-order topological insulator layer 29 above the s-wave superconductor layer 10 and exposes portions of the higher-order topological insulator layer 29 above the lower superconductor layer 61A, the lower superconductor layer 61B, the lower superconductor layer 62A, the lower superconductor layer 62B, the lower superconductor layer 63A, and the lower superconductor layer 63B. As the second electron beam resist, for example, a resist obtained by diluting ZEP 520A (manufactured by Zeon Corporation) with ZEP-A (manufactured by Zeon Corporation) at 1:1 can be used. After the formation of the second mask pattern, the higher-order topological insulator layer 29 and the first transition metal dichalcogenide layer 79 are processed by the Ar ion milling. As a result, the higher-order topological insulator layer 29A and the transition metal dichalcogenide layer 70 are formed, and the lower superconductor layer 61A, the lower superconductor layer 61B, the lower superconductor layer 62A, the lower superconductor layer 62B, the lower superconductor layer 63A, and the lower superconductor layer 63B are exposed from the higher-order topological insulator layer 29A and the transition metal dichalcogenide layer 70. In the Ar ion milling, for example, a beam acceleration voltage is set to 280 V, and a beam current is set to 150 mA.

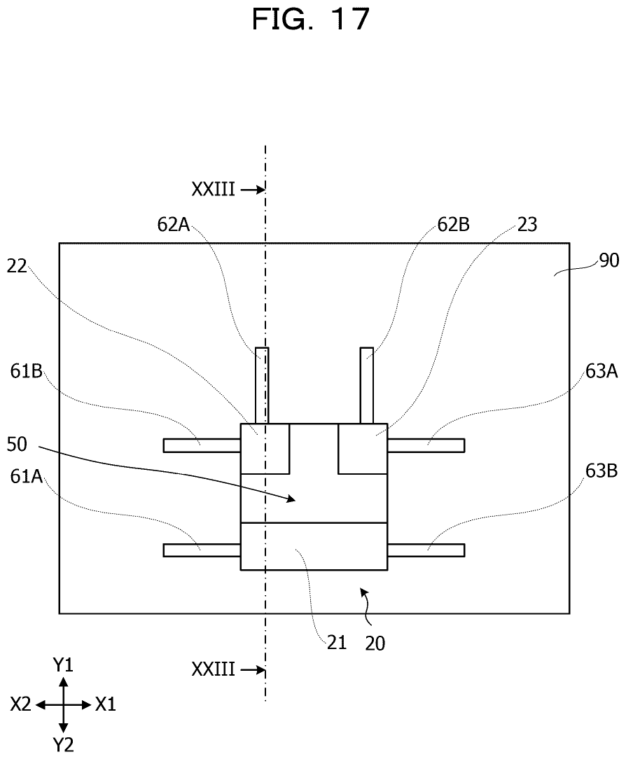

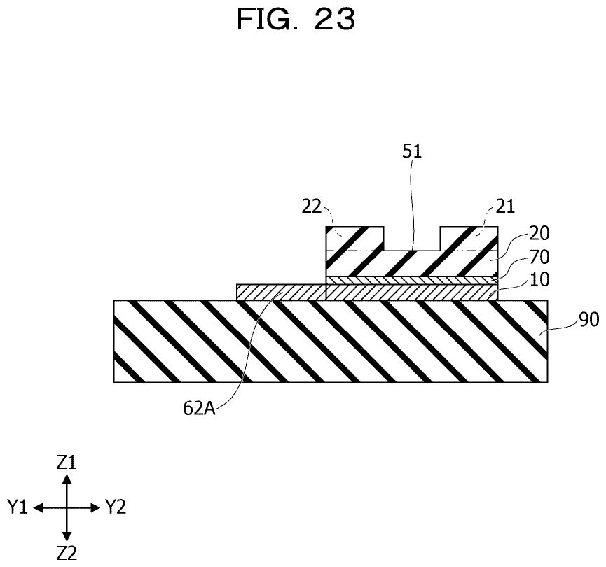

After the formation of the higher-order topological insulator layer 29A and the transition metal dichalcogenide layer 70, the second mask pattern is removed, as illustrated in FIGS. 17 and 23, the higher-order topological insulator layer 29A is processed, and the higher-order topological insulator layer 20 including the first region 21, the second region 22, and the third region 23 is formed from the higher-order topological insulator layer 29A. FIG. 23 corresponds to a cross-sectional view taken along line XXIII-XXIII in FIG. 17.

When the higher-order topological insulator layer 29A is processed, first, the higher-order topological insulator layer 29A, the substrate 90, the lower superconductor layer 61A, the lower superconductor layer 61B, the lower superconductor layer 62A, the lower superconductor layer 62B, the lower superconductor layer 63A, and the lower superconductor layer 63B are spin-coated from above with a third electron beam resist. Next, a third mask pattern is formed from the third electron beam resist by the electron beam lithography. The third mask pattern exposes a portion of the higher-order topological insulator layer 29A where the groove 50 is intended to be formed and covers other portions. As the third electron beam resist, for example, a resist obtained by diluting ZEP 520A (manufactured by Zeon Corporation) with ZEP-A (manufactured by Zeon Corporation) at 1:1 can be used. After the formation of the third mask pattern, the higher-order topological insulator layer 29A is processed by the Ar ion milling. As a result, the groove 50 including the first groove 51, the second groove 52, and the third groove 53 is formed, and the higher-order topological insulator layer 20 including the first region 21, the second region 22, and the third region 23 is obtained. The first region 21 includes the first hinge helical channel 11, the second region 22 includes the second hinge helical channel 12, and the third region 23 includes the third hinge helical channel 13 (refer to FIG. 13). In the Ar ion milling, for example, a beam acceleration voltage is set to 280 V, and a beam current is set to 150 mA.

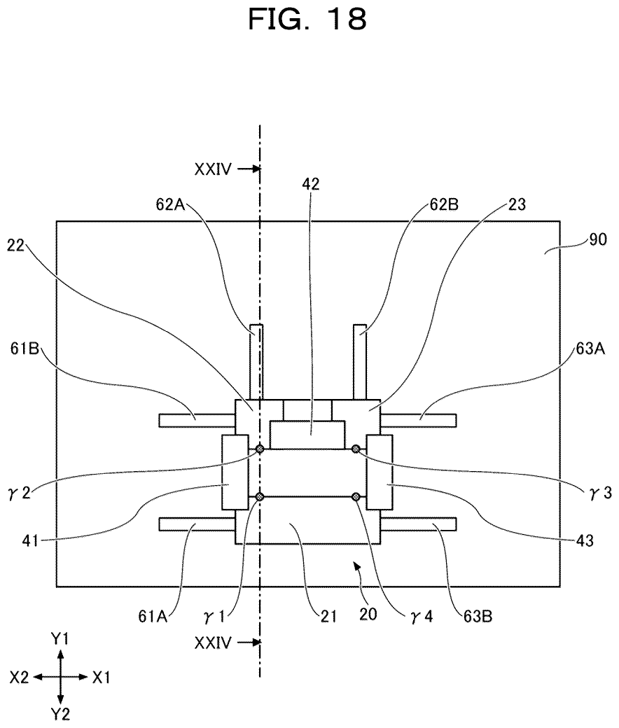

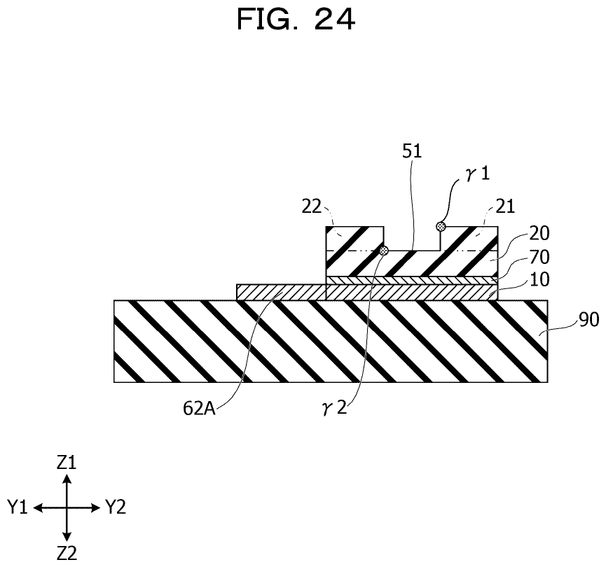

After the formation of the higher-order topological insulator layer 20, the third mask pattern is removed, and as illustrated in FIGS. 18 and 24, the first ferromagnetic insulator layer 31, the second ferromagnetic insulator layer 32, the third ferromagnetic insulator layer 33, the first gate electrode 41, the second gate electrode 42, and the third gate electrode 43 are formed. FIG. 24 corresponds to a cross-sectional view taken along line XXIV-XXIV in FIG. 18.

When the first ferromagnetic insulator layer 31, the second ferromagnetic insulator layer 32, the third ferromagnetic insulator layer 33, the first gate electrode 41, the second gate electrode 42, and the third gate electrode 43 are formed, first, the higher-order topological insulator layer 20, the substrate 90, the lower superconductor layer 61A, the lower superconductor layer 61B, the lower superconductor layer 62A, the lower superconductor layer 62B, the lower superconductor layer 63A, and the lower superconductor layer 63B are spin-coated from above with a fourth electron beam resist. Next, a fourth mask pattern is formed from the fourth electron beam resist by the electron beam lithography. The fourth mask pattern exposes portions where the first ferromagnetic insulator layer 31, the second ferromagnetic insulator layer 32, the third ferromagnetic insulator layer 33, the first gate electrode 41, the second gate electrode 42, and the third gate electrode 43 are intended to be formed and covers other portions. As the fourth electron beam resist, for example, a resist obtained by diluting ZEP 520A (manufactured by Zeon Corporation) with ZEP-A (manufactured by Zeon Corporation) at 1:1 can be used. After the formation of the fourth mask pattern, a Cr₂Ga₂ Te₆ layer and an Au layer are formed by the PLD method.

When the Cr₂Ga₂Te₆ layer is formed by the PLD method, for example, a temperature of the substrate 90 is held at about 200° C., a laser energy density is set to 1.0 J/cm² to 2.0 J/cm², an irradiation frequency is set to 1 Hz, a distance between the substrate 90 and the target is set to about 5 cm, and a film formation rate is set to 1.0 nm/minute to 2.0 nm/minute.

When the Au layer is formed by the PLD method, for example, a temperature of the substrate 90 is held at a room temperature, a laser energy density is set to 1.0 J/cm² to 2.0 J/cm², an irradiation frequency is set to 5 Hz, a distance between the substrate 90 and the target is set to about 5 cm, and a film formation rate is set to 5.0 nm/minute to 10.0 nm/minute.

After the formation of the Cr₂Ga₂Te₆ layer and the Au layer, the fourth mask pattern is removed together with the Cr₂Ga₂Te₆ layer and the Au layer deposited over the fourth mask pattern. For example, lift-off is performed. As a result, the first ferromagnetic insulator layer 31, the second ferromagnetic insulator layer 32, the third ferromagnetic insulator layer 33, the first gate electrode 41, the second gate electrode 42, and the third gate electrode 43 are obtained. Furthermore, the four types of Majorana particles γ1, γ2, γ3, and γ4 are expressed.

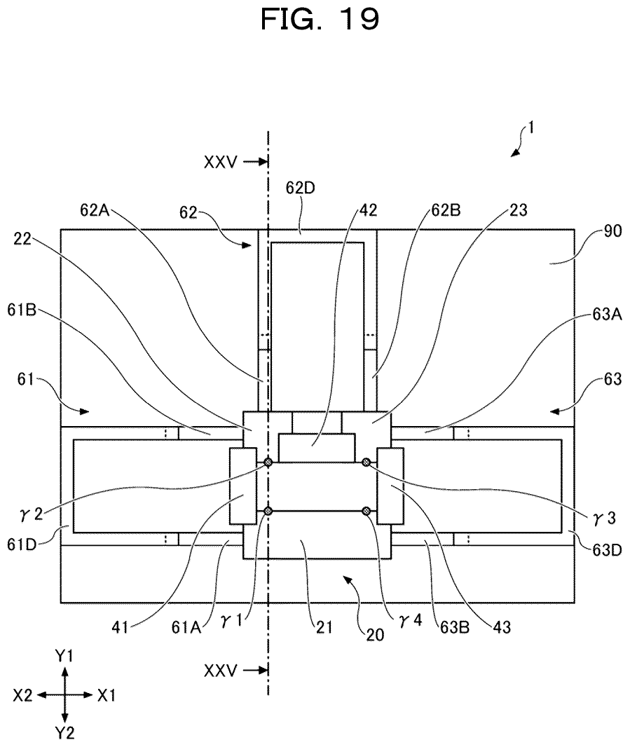

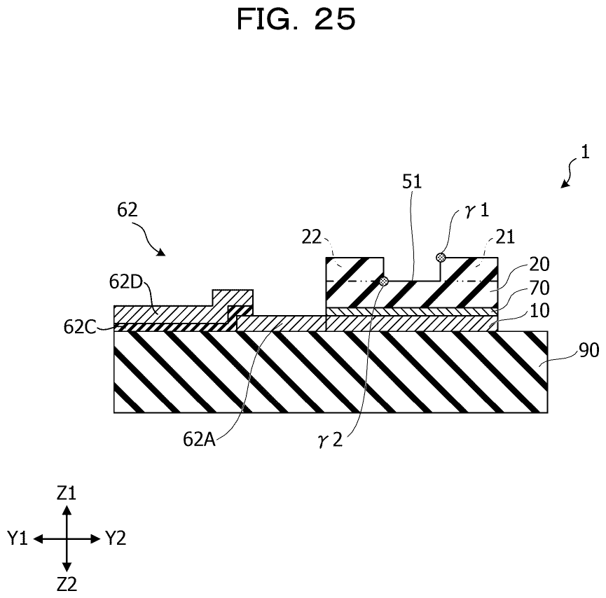

Next, as illustrated in FIGS. 19 and 25, the tunnel barrier layers 61C to 63C and the upper superconductor layers 61D to 63D are formed. FIG. 25 corresponds to a cross-sectional view taken along line XXV-XXV in FIG. 19.

When the tunnel barrier layers 61C to 63C and the upper superconductor layers 61D to 63D are formed, first, the higher-order topological insulator layer 20, the substrate 90, the lower superconductor layer 61A, the lower superconductor layer 61B, the lower superconductor layer 62A, the lower superconductor layer 62B, the lower superconductor layer 63A, the lower superconductor layer 63B, the first gate electrode 41, the second gate electrode 42, and the third gate electrode 43 are spin-coated from above with a fifth electron beam resist. Next, a fifth mask pattern is formed from the fifth electron beam resist by the electron beam lithography. The fifth mask pattern exposes portions where the tunnel barrier layers 61C to 63C and the upper superconductor layers 61D to 63D are intended to be formed and covers other portions. As the fifth electron beam resist, for example, a resist obtained by diluting ZEP 520A (manufactured by Zeon Corporation) with ZEP-A manufactured by Zeon Corporation) at 1:1 can be used. After the formation of the fifth mask pattern, a NbOₓ layer and a Nb layer are formed by the PLD method.

When the NbOₓ layer is formed by the PLD method, for example, a Nb metal target is used, a temperature of the substrate 90 is held at a room temperature, and an oxygen partial pressure of a vacuum chamber is adjusted to about 50 Pa to 55 Pa. The Nb layer can be formed under conditions similar to those for the s-wave superconductor layer 19.

After the formation of the NbOₓ layer and the Nb layer, the fifth mask pattern is removed together with the NbOₓ layer and the Nb layer deposited over the fifth mask pattern. For example, lift-off is performed. As a result, the tunnel barrier layers 61C to 63C and the upper superconductor layers 61D to 63D are obtained, and the first SQUID 61, the second SQUID 62, and the third SQUID 63 are formed.

In this way, the quantum bit 1 according to the second embodiment can be manufactured.

Note that, in the present disclosure, the material of the s-wave superconductor layer is not limited to Nb. The material of the s-wave superconductor layer may be lead (Pb). The material of the chalcogen layer is not limited to Te. The material of the chalcogen layer may be sulfur (S) or selenium (Se). The material of the chalcogen layer may be of the same kind as the chalcogen element contained in the second transition metal dichalcogenide layer. The material of the metal layer is not limited to Nb. The material of the metal layer may be Pb. The transition metal contained in the s-wave superconductor layer and the transition metal contained in the metal layer are preferably of the same kind, but may be different from each other. If the transition metal contained in the s-wave superconductor layer and the transition metal contained in the metal layer are of the same kind, the transition metal dichalcogenide contained in the first transition metal dichalcogenide layer tends to be of one kind. On the other hand, in a case where the transition metal contained in the s-wave superconductor layer is different from the transition metal contained in the metal layer, two or more kinds of transition metal dichalcogenides may be sometimes contained in the first transition metal dichalcogenide layer. Even when the first transition metal dichalcogenide layer contains two or more kinds of transition metal dichalcogenides, excellent crystallinity may be obtained in the second transition metal dichalcogenide layer. The chalcogen element contained in the first transition metal dichalcogenide layer and the chalcogen element contained in the second transition metal dichalcogenide layer may be of the same kind.

In the present disclosure, the material of the second transition metal dichalcogenide layer (including the higher-order topological insulator layer) is not limited to WTe₂. The second transition metal dichalcogenide layer may contain molybdenum (Mo), Nb, tungsten (W), tantalum (Ta), titanium (Ti), zirconium (Zr), iron (Fe), palladium (Pd), iridium (Ir), or platinum (Pt), or any combination thereof as a transition metal. The layered material contained in the second transition metal dichalcogenide layer may be a single layer.

### Third Embodiment

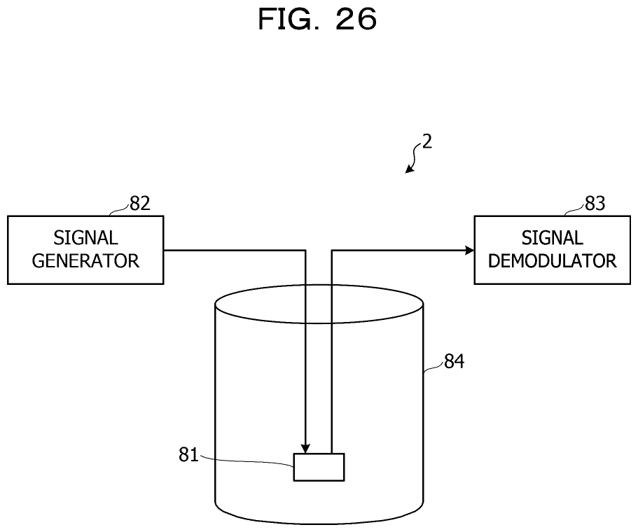

Next, a third embodiment will be described. A third embodiment relates to a quantum operation device including the quantum bit 1 according to the second embodiment. FIG. 26 is a diagram illustrating the quantum operation device according to the third embodiment.

A quantum operation device 2 according to the third embodiment includes a quantum bit chip 81, a signal generator 82, a signal demodulator 83, and a cryogenic dilution refrigerator 84, as illustrated in FIG. 26. The quantum bit chip 81 includes a plurality of the quantum bits 1 according to the second embodiment. The quantum bit chip 81 is housed in the cryogenic dilution refrigerator 84 and is cooled to a temperature equal to or lower than 10 mK. The signal generator 82 generates a microwave pulse signal, and the microwave pulse signal is input to the quantum bit chip 81. The quantum bit chip 81 outputs a signal according to the microwave pulse signal, and the signal demodulator 83 demodulates the signal output from the quantum bit chip 81. The signal generator 82 and the signal demodulator 83 are used, for example, at a temperature of about room temperature.

Since the quantum operation device 2 according to the third embodiment includes the quantum bit 1 according to the second embodiment, the Majorana particles may be stably expressed, and operations may be stably performed.

Although the preferred embodiments and the like have been described in detail so far, the embodiments are not restricted to the above-described embodiments and the like, and various modifications and substitutions can be made to the embodiments and the like described above, without departing from the scope disclosed in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A method for manufacturing a structure comprising:
forming an s-wave superconductor layer over a base material;
forming a first transition metal dichalcogenide layer that contains a van der Waals layered material, over the s-wave superconductor layer; and
forming a second transition metal dichalcogenide layer over the first transition metal dichalcogenide layer.

2. The method according to claim 1, wherein the second transition metal dichalcogenide layer is a higher-order topological insulator layer that contains a plurality of transition metal dichalcogenides laminated over the first transition metal dichalcogenide layer.

3. The method according to claim 1, wherein
the forming the first transition metal dichalcogenide layer includes:
forming a chalcogen layer over the s-wave superconductor layer;
forming a metal layer that contains a transition metal, over the chalcogen layer; and
heating the chalcogen layer and the metal layer.

4. The method according to claim 3, wherein the chalcogen layer contains sulfur (S), selenium (Se), or tellurium (Te), or any combination of S, Se, or Te.

5. The method according to claim 3, wherein the s-wave superconductor layer is constituted by the transition metal of a same kind as the transition metal contained in the metal layer.

6. The method according to claim 1, wherein the s-wave superconductor layer contains niobium (Nb) or lead (Pb).

7. The method according to claim 3, wherein a chalcogen element contained in the first transition metal dichalcogenide layer and the chalcogen element contained in the second transition metal dichalcogenide layer are of a same kind.

8. A structure comprising:
a base material;
an s-wave superconductor layer provided over the base material;
a first transition metal dichalcogenide layer that is provided over the s-wave superconductor layer and contains a van der Waals layered material; and
a second transition metal dichalcogenide layer provided over the first transition metal dichalcogenide layer.

9. The structure according to claim 8, wherein the second transition metal dichalcogenide layer is a higher-order topological insulator layer that contains a plurality of transition metal dichalcogenides laminated over the first transition metal dichalcogenide layer.

10. The structure according to claim 8, wherein the first transition metal dichalcogenide layer contains S, Se, or Te, or any combination of S, Se, or Te.

11. The structure according to claim 8, wherein the s-wave superconductor layer is constituted by a transition metal of a same kind as the transition metal contained in the first transition metal dichalcogenide layer.

12. The structure according to claim 8, wherein the s-wave superconductor layer contains Nb or Pb.

13. A quantum bit comprising:
an s-wave superconductor layer;
a transition metal dichalcogenide layer that is provided over the s-wave superconductor layer and contains a van der Waals layered material;
a higher-order topological insulator layer provided over the transition metal dichalcogenide layer;
a first ferromagnetic insulator layer provided over the higher-order topological insulator layer; and
a first gate electrode provided over the first ferromagnetic insulator layer, wherein
the higher-order topological insulator layer
includes:
a first region that includes a first hinge helical channel, and
a second region that includes a second hinge helical channel separated from the first hinge helical channel, and
the first ferromagnetic insulator layer covers the first hinge helical channel and the second hinge helical channel.

14. The quantum bit according to claim 13, comprising a first superconducting quantum interference device configured to detect a change in a magnetic flux between the first hinge helical channel and the second hinge helical channel.

15. The quantum bit according to claim 13, wherein
the higher-order topological insulator layer includes a third region that includes a third hinge helical channel separated from the first hinge helical channel and the second hinge helical channel, and
the quantum bit comprises: a second ferromagnetic insulator layer that covers the second hinge helical channel and the third hinge helical channel;
a second gate electrode provided over the second ferromagnetic insulator layer;
a third ferromagnetic insulator layer that covers the third hinge helical channel and the first hinge helical channel; and
a third gate electrode provided over the third ferromagnetic insulator layer.

16. The quantum bit according to claim 15, comprising:
a second superconducting quantum interference device; and
a third superconducting quantum interference device, wherein
the second superconducting quantum interference device detects a change in a magnetic flux between the second hinge helical channel and the third hinge helical channel, and
the third superconducting quantum interference device detects the change in the magnetic flux between the third hinge helical channel and the first hinge helical channel.

17. The quantum bit according to claim 15, wherein
in the higher-order topological insulator layer,
a first groove that defines the first region and the second region,
a second groove that defines the second region and the third region, and
a third groove that defines the third region and the first region are formed.

18. The quantum bit according to claim 17, wherein the first groove and the third groove extend in a first direction that is common to the first groove and the third groove,
the second groove extends in a second direction perpendicular to the first direction, and
the first groove, the second groove, and the third groove are connected.

19. The quantum bit according to claim 18, wherein the first groove, the second groove, and the third groove configure a T-shaped groove in planar view.

20. The quantum bit according to claim 13, wherein the s-wave superconductor layer contains Nb or Pb.
